(19) United States
(12) Patent Application Publication
(10) Pub. No.: US 2025/0338634 A1
(43) Pub. Date: Oct. 30, 2025

(54) CUMULATIVE POLARIZATION COEXISTING WITH CONDUCTIVITY AT INTERFACIAL FERROELECTRICS

(71) Applicant: Ramot at Tel-Aviv University Ltd., Tel Aviv (IL)

(72) Inventor: Moshe BEN SHALOM, Tel Aviv (IL)

(73) Assignee: Ramot at Tel-Aviv University Ltd., Tel Aviv (IL)

(21) Appl. No.: 18/869,977

(22) PCT Filed: Jun. 21, 2023
(86) PCT No.: PCT/IL2023/050644

§ 371 Date: Nov. 27, 2024

Related U.S. Application Data
(60) Provisional application No. 63/366,715, filed on Jun. 21, 2022.

(51) Int. Cl. H10F 10/142; H10F 77/169

(52) U.S. Cl. CPC H10F 10/142; H10F 77/1696

(57) ABSTRACT

The technology disclosed herein is based on a novel multilayer material having a plurality of internal charge dipoles and in-plane conductivity.

The project leading to this application has received funding from the European Research Council (ERC) under the European Union's Horizon 2020 research and innovation program (grant agreement No 852925)

### FIELD OF THE INVENTION

The technology disclosed herein generally concerns conductive and polarized interfacial ferroelectric devices and uses thereof.

### BACKGROUND

Ferroelectricity in atomically thin bilayer structures was predicted and measured in two-dimensional (2D) materials with hexagonal non-centrosymmetric unit-cells. Interestingly, the crystal symmetry translates lateral shifts between parallel 2D layers to a change of sign in their out-of-plane electric polarization, a mechanism referred to as “Slide-Tronics”. These observations, however, have been restricted to switching between only two polarization states under low charge carrier densities, strongly limiting the practical application of the revealed phenomena [1].

### PUBLICATIONS

[1] International patent publication no. WO 2022/064505.

### SUMMARY OF THE INVENTION

For the first time, 2D materials have been formed to simultaneously exhibit non-volatile memory and rapid logic responses, where internal charge dipoles (defining out-of-place polarizations) and free electrons (in-plane conductivity) coexist. As disclosed herein, the in-plane conductivity was afforded by a conducting 2D material, whereas out-of-plane switchable polarization emerged from breaking or interrupting the material intrinsic symmetry at the interface. This inherent anisotropy of layered ferroelectrics distinguishes them from thin ferroelectric films (such as those disclosed in [1]), which are highly susceptible to depolarizing fields at the surface or interface where the polarization terminates. Specifically, at the 2D limit, the polarization magnitude rarely scales with the system thickness and can switch between two local states only.

Thus, the inventors contemplate a multilayer material (referred to equivalent as a stacked layer material or a multilayer structure) having two or more layers of a 2D material, at least one of the two or more layers being a layer of a doped 2D material, wherein using the 2D material layers, as disclosed, provides a plurality of internal charge dipoles and in-plane conductivity. The multilayer materials of the invention may comprise any number of 2D material layers and any number of doped 2D material layers, provided that some or all of the material layers are of doped 2D materials. Each of the 2D material layers may be of the same or different 2D material. In some configurations, each of the layers of the 2D material is doped; namely all material layers are doped. In some other configurations, only some or a few of the layers are formed of a doped 2D material. Similarly, in some configurations, each of the material layers may be of the same 2D material, while in others, the multilayer may comprise a plurality of different material layers, differing in composition, doping material charge density, etc. Notwithstanding the number of 2D material layers (being two or more), the type of 2D material used, the homogeneity or heterogeneity of the material (in terms of layer composition), the presence of one or more layers of a doped 2D material and the type of dopant used, the material exhibits a high in-plane conductivity that does not suppress or limit the out-of-plane polarization states.

In a first aspect, there is provided a multilayer material or structure comprising two or more stacked layers of a 2D material, wherein at least one of said two or more layers of a 2D material is a layer of a doped 2D material, and wherein the multilayer material or structure exhibiting (simultaneously) in-plane conductivity, and an out-of-plane switchable polarization.

With the ability to pre-set the polarization states in a multilayer material or structure, even in the presence of charge carriers, the structure can operate as a multi-switch device having pre-determined multi-switch polarization states. Each of the states is determined by summing up the (total) number of interfaces having a polarization pointing in one direction (e.g., “up”) normal to the multilayer plane, minus the number of interfaces with a polarization pointing in the opposite direction (e.g., down).

In typical scenarios and as mentioned above, it would be expected that presence of charge carriers (electrons or holes) in a system of any number of polarization states, rendering the system conductive or, in some cases, of increased or improved conductivity, will cause a suppression of the intrinsic electric field and eventually cancel it. Surprisingly, such a suppression is not observed in materials and devices implementing materials of the invention. In cases where the extrinsic charge resides mostly on one of the layers, hence countering the global polarization (FIG. 1 for WSe₂, for holes added to the valence band edge at K point), the maximal doping charge density before losing polarization is limited, e.g., to approximately n≈10¹³ cm⁻². However, for systems of the invention using 2D materials, such as MoS₂, having a delocalized band edge (valence band at Γ point in the case of MoS₂), the doping effect is distributed fairly evenly between the doped layers. Thus, despite the existence or increase in charge carriers (FIG. 5), the even distribution does not eliminate polarization, allowing the maximal doping charge density to increase to as high as n≈10¹⁴ cm⁻², which is 10 times larger.

Thus, the invention further provides a multilayer material having a plurality of out-of-plane switchable polarization states, the multilayer material comprising two or more stacked layers of a 2D material, wherein at least one of the layers formed of the 2D material is doped with charge carriers or holes (electrons or holes) that are substantially evenly distributed in the material layer(s), thereby inducing in-plane conductivity.

In some embodiments, the charge carriers (electrons or holes) are substantially distributed equally over all layers of the multilayer material.

As used herein, the expression “substantially evenly distributed” or “substantially distributed equally” encompasses distribution of the charge carriers that is not localized to one of the layers nor to any one particular region within any given layer. Typically, the charges have sufficient mobility to distribute evenly over several layers of the multilayer structure.

The invention further provides a conductive device comprising a stacked multilayer of two or more layers of a 2D material, at least one of which being a layer of a doped 2D material, each layer of the two or more layers of the 2D material having a global (cumulative) polarization (the overall polarization state of the material or device) pointing in a direction normal to a direction of conductivity.

The invention further provides a device comprising a multilayer of two or more layers of a doped 2D material exhibiting in-plane conductivity, wherein each layer having a polarization pointing in a direction normal to the multilayer plane and opposite to the direction of polarization of any adjacent layer.

As disclosed herein, materials and devices of the invention are multilayer structures of two or more layers which are stacked one on top of the other such that each layer has a polarization pointing in a direction normal to the multilayer plane and opposite to the direction of polarization of any adjacent or neighboring layer. For example, in a multilayer structure comprising three stacked material layers designated (a), (b) and (c), wherein layer (b) is sandwiched between layers (a) and (c), each of layers (a) and (b) has a polarization pointing in a direction normal to the multilayer plane, while for layer (a) the direction of polarization is different from that of (b). Similarly, the direction of polarization of layer (b) is different from that of layer (c). Same configuration applies to multilayers of more than three stacked layers. The conductivity, however, present in each doped layer unexpectedly also exhibiting polarization, is substantially present along the plane of the system.

The “2D material” used as herein is typically a single layer material or monolayer-type material that is atomically thin crystalline solid having intralayer covalent bonding and interlayer van der Waals bonding. A non-limiting example of such a material is h-BN in which the boron atoms and atoms of nitrogen are bound strongly due to covalent bonds present in-plane and van der Waals forces that hold the layer together. Each of the material layers forming a multilayer structure of the invention is formed of a 2D material that may be a 2D semiconductor material. In some cases, the 2D material is a diatomic hexagonal material. The diatomic hexagonal layered materials are generally 2D materials having hexagonal lattice with three-fold symmetry and which permit mirror plane symmetry and/or inversion symmetry. The materials are provided as exfoliated layers or alternatively in a grown layered form, for example by chemical vapor deposition (CVD) or by any similar growth method of thin layers, which can be assembled into a stack in a substantially parallel lattice orientation of the individual layers.

In some embodiments, the diatomic hexagonal material may be hexagonal-boron-nitride (h-BN), transition-metal-dichalcogenides (TMD), hexagonal-aluminum-nitride (h-AlN), hexagonal-zinc-oxide (h-ZnO), hexagonal-gallium-nitride (h-GaN), and others as known in the art.

As known in the art, hexagonal boron nitride, h-BN, is a ceramic material known for its high thermal conductivity, inertness, and tribological properties that render it interesting in a variety of applications. The material also finds its unique applications in polymer composites for high temperature applications and sp3 bonding in extreme temperature and compression conditions. The structural texture of h-BN is a layered structure, wherein the boron atoms and atoms of nitrogen are bound strongly due to covalent bonds present in-plane and van der Waals forces that hold the layer together.

Transition-metal-dichalcogenides (TMD) are 2D materials exhibiting unique electrical, mechanical, and optical properties and are therefore of virtually unlimited potential in various fields, including electronic, optoelectronic, sensing, and energy storage applications. Non-limiting examples of these layered materials include MoS₂, WS₂, MoSe₂ and WSe₂.

Thus, in some embodiments, the diatomic hexagonal layered material is selected from h-BN, TMD such as MoS₂, WS₂, MoSe₂ and WSe₂ and others.

In some embodiments, materials and devices of the invention are based on 2D semiconductor materials such as MoS₂, WS₂, MoSe₂ and WSe₂.

In some embodiments, materials and devices of the invention are based on 2D materials such as MoS₂, WS₂, MoSe₂ and WSe₂.

The invention further provides a conductive stacked multilayer diatomic hexagonal material or a conductive stacked multilayer structure formed by orienting any two stacked layers of a doped diatomic hexagonal material into a stacked substantially parallel lattice orientation to induce internal interfacial electric field normal to the layers plane at an interface between the two stacked material layers and in-plane conductivity.

The conductivity of a multilayer material, structure or a device of the invention refers to a measured ability of the material or structure to conduct electric current due to presence of charges that are of sufficient mobility to distribute evenly over the layers of the multilayer material or structure. As noted herein, in-plane conductivity is afforded by a conducting 2D material; namely a 2D material that has been doped with charge carriers prior to or after the multilayered material has been formed. Thus, multilayer materials, structures and devices implementing same which are not doped, by any way, as disclosed herein, are excluded or outside the scope of the present invention.

The “in-plane conductivity” should be understood as a direction within the plane of the doped layers, or within a plane that is perpendicular to the thickness of the multilayer or the direction of polarization (being normal to the plane).

The term “doping” encompasses any method known and used to introduce charge carriers into a material to confer conductivity thereto. The doping process may involve chemical doping of the 2D materials prior to assembling the multilayer structure or electrostatic doping of an undoped multilayer structure by external gates. Any doping scheme may be utilized. In some cases, chemical doping may be used and involve substitution of only metal ions, or only chalcogen ions, while electrostatic doping may be used to substitute any of the metal or chalcogen ions in the 2D material, to produce p-doped or n-doped materials.

In some embodiments, the doped multilayer materials or structures of the invention are formed by chemical doping of the 2D materials prior to forming the multilayer structure. Chemical doping may involve such methodologies as diffusion or ion injection procedures, as known in the art.

In some embodiments, the doped structures may be formed by first forming the multilayer material or structure followed by doping same by electrostatic doping. The electrostatic doping may involve application of voltage over the 2D material so as to add charge carriers, the nature of which depending on the voltage applied.

Processes of chemical and electrostatic doping are known in the art.

In some embodiments, the 2D material used according to the invention is n-doped. In other cases, it is p-doped. In some embodiments, an undoped, not conductive multilayer structure of a 2D material is doped by electrostatic methodologies to afford the conductive material or structure.

While the extent of doping may be unlimited in terms of the selection of a doping atom and doping density or charge carrier concentration (or distribution), the doping density may be controlled or limited by such factors including, inter alia, the material to be doped, the type of dopant, the doping conditions used, and others. As a general rule, doping does not alter nor substantially affect the polarization of the system. As demonstrated herein, minor deviations of the band-structures of the doped systems from those of the undoped counterparts have been observed, even at the very high doping densities. Generally, the charge densities may reach values as high as 10¹⁴ cm⁻². In some embodiments, the charge density may be between 10¹⁰ cm⁻² and 10¹⁴ cm⁻² or between 10¹³ cm⁻² and 10¹⁴ cm⁻².

In some embodiments, a multilayer structure of the invention comprising two or more stacked layers of a 2D material exhibiting out-of-plane switchable polarization, as disclosed herein and comprising free charge carriers of a density that is at least 10¹⁰ cm⁻² or between 10¹⁰ cm⁻² and 10¹⁴ cm⁻² or between 10¹³ cm⁻² and 10¹⁴ cm⁻². In some embodiments, the charge carriers are evenly distributed in the multilayer structure.

Materials and devices of the invention may comprise a plurality of layers and interfaces, at least one of which is p- or n-doped. The addition of layers may decrease the band gap of the material or device by an amount equivalent to the potential energy drop measured (FIG. 1). Since systems of the invention are, in some cases, semiconducting, the energy gap is fairly limited, and a finite number of layers may cause the bandgap to close and generate metallic surface states which are oppositely charged at the top and bottom layers of the structure. These surface states, with free charge carriers will cause the system out-of-plane polarization to saturate to a given value, comparable to the gap energy of the pristine system. In practice, the finite intrinsic doping present due to defects and contaminants causes polarization saturation to a lower value at lower layer count. For example, in the case of MoS₂ (band gap=˜1.6 eV), stacking 8 to 12 layers will saturate the polarization of the system, whereas for WSe₂ (band gap=˜1.3 eV), a stack of around 16 layers will saturate the polarization (FIGS. 2A-B).

Doping of the 2D semiconductor materials, while not quenching the polarization of the system, provides an opportunity of using these materials in applications that were not available for systems having low in-plane conductivity or having no polarization. In other words, while systems such as those disclosed in reference [1] above exhibit superior polarization, they exhibit no in-plane conductivity, or exhibit a resistivity larger than 100 Kohm/square, and thus may not be implemented in applications where both conductivity and polarization effects are needed. Any accidental or unintentional doping that may be a result of un-controlled contamination by impurities, is believed not to induce any conductivity as compared to systems of the invention.

The most prominent application that arises from materials of the invention is the use of these materials as photovoltaics. The out-of-plane polarization allows photoinduced excitons formed within a semiconductor to separate efficiently without the need of an external bias, this can drive a photocurrent at high efficiency.

As the physical movement of the layers in respect to each other can switch the polarization of the structure, thereby driving the movement of charges between layers, to oppose the polarization, materials of the invention may also be used in non-volatile storage technologies such as microelectromechanical systems (MEMS). A continuous movement of layers in a fixed direction, or the repetitive back and forth movement will cause an oscillating charge movement and effectively will produce an alternating current. This can be perceived as a current generator.

Materials of the invention may be further used as polar diodes or memristors. In such applications, the reading of the state of the system can be done efficiently by measuring the in-plane conductivity, instead of tunneling currents in a non-doped system.

Thus, the invention further provides use of a material of the invention in constructing or manufacturing an electronic, optical or photoelectronic device. Such devices may be non-volatile memory devices, MEMS, photovoltaic cells, field effect transistors, memristors, and polar diodes.

Further provided is a device implementing or incorporating a material according to the invention.

Devices of the invention are typically structured of a multilayer material or structure, as disclosed herein, and an electrode assembly which comprises a pair of electrodes positioned at the edges of the layers (one electrode at each edge defined by the main axis or plane of the multilayer structure). The position at the edges, rather than above and below the top surface of the structure, allows current in the doped layer(s). A gate electrode may be additionally positioned above and below the multilayer structure for switching of the polarization.

Thus, a device of the invention comprises or incorporates a multilayer structure according to the invention, an electrode assembly comprising an electrode positioned at each edge of the multilayer structure, and an electrode positioned at each of the top and bottom of the structure (a total of two sets of electrodes).

In some embodiments, the device is selected from non-volatile memory devices, MEMS, photovoltaic cells, field effect transistors, memristors, and polar diodes.

In some embodiments, the device is a photovoltaic device.

To demonstrate and explore the potential of interfacial ferroelectrics, devices were studied which were made of two or three or more layers of transition metal dichalcogenides (TMDs) that are artificially stacked in a parallel lattice orientation and encapsulated by thin flakes of non-polar hexagonal boron nitride (h-BN), placed atop a graphite or gold metallic electrode (FIG. 3A). The electric potential at room temperature, ˜10 nm above the surface was measured with an atomic force microscope operated in a side-band Kelvin probe mode (KPFM). The obtained potential map is presented in FIG. 3B, showing a triangular domain landscape of various polarization values, separated by thin domain walls that naturally form due to a slight twist angle between the flakes. These domain walls accommodate a shear displacement of one interatomic spacing, allowing for high symmetry AB/BA stacking within the triangular domains. Measuring the potential profile across domain walls, five distinct polarization values (FIG. 3C) were identified. The potential profile measured in the top-left triangular region in FIG. 3B (red line) exhibited two polarization states, consistent with previous reports on non-centrosymmetric bilayer TMDs incorporating a single polar interface. This indicates regions of the WSe₂ trilayer where only one of the two interfaces is active, namely exhibiting finite polarization due to non-centrosymmetric stacking and in-plane atomic relaxation. Notably, the corresponding profile measured at the central region (dashed line) shows three polarization states separated by potential steps of ΔV_{KP}˜110 mV (FIG. 3C). The potential of the intermediate step is the average of the two potential values corresponding to a single active-interface trilayer, suggesting two oppositely polarized (↑↓) interfaces within a trilayer WSe₂ region, as in the case of mirror-symmetric Bernal stacking (ABA) of Wse₂. This interpretation was further supported by the fact that the potential differences between the three polarization states equal those measured at the single-active interface regions, which translates to absolute polarization values twice as large as those measured for the bilayer system. This, in turn, can be achieved if the two interfaces have parallel polarizations (↑↑, ↓↓), which is the case for the rhombohedral ABC and CBA stacking configurations.

The experimental evidence indicates that the polarization should be localized at the interfaces between layers, suggesting that adjacent interfaces are only weakly coupled and, therefore, a cumulative polarization effect in layered stacks is obtained. This was further supported by the comparable coverage of the ABC and ABA domains in the map, demonstrating no significant energetic stability preference between the two stacking configurations. The former domain, which has two aligned polar interfaces, thus exhibits a similar stacking energy to that of the latter domains, which include two anti-aligned polar interfaces. It is worth noting, however, that for larger domains small coverage differences are observed, indicating weak Ferro-like coupling that favors a co-aligned polar ABC configuration. This was further supported by the comparable coverage of ABC and ABA domains in the map owing to comparable adhesion energies in the two-stacking configuration. Finite differences, though, observed for large domains point to weak Ferro-like coupling that favors a co-polar ABC configuration. FIG. 3D presents DFT-computed potential profiles for the ABC stacked WSe₂ trilayer. The difference in the calculated potential, Δϕ, far above and below the layered system is in good agreement with the measured potential drop (ΔV_{KP}=2Δϕ) and its step-like shape emphasizes the interfacial confinement of the polarization and hence the weak coupling between adjacent polarized interfaces. Adding more parallelly-polarized layers in the computation reveals an essentially linear increase of the total polarization with stack thickness (FIG. 1E, light grey), confirming a cumulative interfacial effect. Furthermore, adding AB stacked layers does not affect the overall polarization (black line) due to mirror symmetry, as also observed for h-BN.

To demonstrate the emergence of multi-polarization states beyond tri-layered stacks, the potential was measured at the surface of MoS₂ crystals, which are naturally grown in the 3R ABC stacking configuration. The addition of layers with aligned polarization resulted in an essentially linear increase of the total polarization with stack thickness (FIGS. 4A, B and E), confirming the cumulative interfacial effect. Remarkably, some regions of the flakes reveal various potential values indicative of multiple interfacial polarization configurations (FIGS. 4C,D) of aligned and anti-aligned polarized interfaces. For a given number of layers, regions of different stacking and polarization are spatially separated by local domain walls, whose crossing results in evenly spaced potential steps. The specific value of the measured potential above each region is determined by the difference between upward (N↑) and downward (N↓) polarization pointing active interfaces, which is dictated by the local stacking configuration and can be extracted from the measured local potential (FIG. 4F). In the case of 7 layers, for example, with N=6 interfaces the system can exhibit N+1 polarization values. Therefore, by a relative shift of each pair of adjacent layers one could, in principle, increase or decrease the surface potential in a sequential ladder of polarization values.

The interface-localized nature of the polarization paves the way to an even more unusual effect, namely its coexistence with in-plane conductance through the individual layers. This possibility was further studied by introducing external gate electrodes to induce free charge carriers in polarized MoS₂ or Wse₂ bilayers. In FIGS. 1A, C, the potential surface of the same spatial MoS₂ region was mapped while applying several fixed gate biases V_{g}. Already upon the application of a relatively small bias, one notices a conductance response (FIG. 8C), as well as an improvement in the map quality (FIGS. 1A-B), indicating that, indeed, the gate bias affects the carrier density in the bilayers. The application of a larger gate bias leads to domain wall sliding and a reversible polarization orientation switching, as reported here and previously for bilayer systems. The results of ΔV_{KP} measurements under different gate biases are presented in FIG. 5D for MoS₂ (stars) and Wse₂ (triangles and circles) bilayers. The displacement field D and the carrier density n for each gate bias value are extracted from the change in the average surface potential, V_{avg}, between the two domains (marked in FIG. 3C). This procedure is insensitive to effects such as quantum capacitance or Schottky barriers (note that the latter prevent the attainments of hole doping in MoS₂). Notably, the polarization in both materials is sustained up to the highest experimentally accessible charge density of n≈10¹³ cm⁻². A reduction of 25-50% in the polarization, however, is observed at n≈±3×10¹² cm⁻². These findings are in qualitative agreement with DFT calculations, also shown in FIG. 5D (solid and dashed lines for MoS₂ and Wse₂, respectively), in which doping is introduced by the inclusion of “pseudoatoms” with fractional nuclear charges, allowing the introduction of excess free charge carriers without violating sample neutrality and without distorting the underlying band-structure. The experimental polarization is known to provide a lower bound to the true polarization, owing to limitations of the local potential measurements under external bias and screening effects due to contaminants accumulating atop the surface at large carrier densities. This explains the underestimation of the experimental measurements with respect to the calculated values. Notably, a qualitative difference between the calculated MoS₂ and Wse₂ polarization response to doping is observed, where the former exhibits a weaker response to hole doping than to electron doping, whereas the latter exhibits an opposite trend.

To rationalize these results, the effect of doping on the charge density distribution and its relation to the observed depolarization were further analyzed. FIGS. 1A-B present the calculated laterally averaged excess electron charge density profiles, ρ₀^{ex}(z), for the undoped MoS₂ (a) and Wse₂ (b) bilayers, where ρ₀^{ex}(z) is defined as the difference between the density of the bilayer and the superposition of the densities of the corresponding undoped infinitely separated layers (dashed black lines). The excess density features a similar prominent asymmetric contribution at the interface between the two layers for both the MoS₂ and WSe₂ bilayer systems, which is the origin of the interface dipole shown in FIG. 3D. Doping-induced excess charge density variations, Δρ^{ex}(z), are represented by colored lines for different hole densities. With increasing doping density, excess charge accumulates primarily within the layers at the transition metal plane. To analyze the asymmetry of the doping induced excess charge, which is responsible for depolarization, we plot in FIGS. 1C-D the antisymmetric part of Δρ^{ex}(z), defined as Δρ^{ex}(z)−Δρ^{ex}(−z), where z=0 is set at the interlayer region center. For both MoS₂ and Wse₂, the asymmetric part of the excess charge shows two contributions, one at the interface and the other within the layers. It was found, however, that two important differences exist in the doping response of Δρ^{ex}(z) in the two materials: (i) At a given hole doping density the overall charge distribution asymmetry is larger for WSe₂ (see red lines); (ii) When integrating over the layer region excluding the interface (z≳0.15 nm) the asymmetric contribution of MoS₂ largely averages out, whereas that of Wse₂ does not. Note that this contribution has a stronger depolarization effect due to its larger distance from the interface. Due to both factors, depolarization is expected to commence at a much lower hole doping value in WSe₂ than MoS₂ (see FIG. 6 for comparison).

Finally, to explain the computationally predicted asymmetry between the polarization response to electron and hole doping, the band structures of the two interfaces, were plotted, FIG. 1E-F, colored according to the relative contribution of the two layers to each k-dependent state, Φₖ(x, y, z). To This end, the projection on the top layer was predicted as

$${P}_{k}^{Top} = {\int }_{- ∞}^{∞} dx {\int }_{- ∞}^{∞} dy {\int }_{0}^{∞} dz {\vert {ϕ}_{k} ( x , y , z ) \vert}^{2} ,$$

with the corresponding projection on the bottom layer given by

$${P}_{k}^{Bot} = 1 - {P}_{k}^{Top} .$$

This analysis clearly shows that the valence band maximum Γ states, which split considerably upon the formation of the bilayer structure, are delocalized over both layers. Similar behavior is found for the conduction band states at the Q point (positioned at the midpoint between the Γ and K points of the Brillouin zone), Q_{CB}, at the bottom of the conduction band. Conversely, the corresponding K-point states are localized on either of the layers and split to a much smaller extent (comparable to ΔV_{KP}/2), mainly due to the emergent interface dipole. Therefore, changes in the occupation of the latter states will have a significant effect on the polarization. FIG. 1E shows that for MoS₂ the K_{CB} states are encountered earlier upon raising the Fermi level (electron doping), whereas Γ_{VB} states are encountered earlier upon lowering the Fermi level (hole doping). This explains the trend observed in FIG. 1D (solid black line), namely that depolarization commences at lower electron doping in MoS₂. FIG. 1F predicts an opposite behavior for WSe₂, owing to a much larger spin-orbit coupling induced upshift of the layer polarized K_{VB} states and downshift of the layer delocalized Q_{CB} states, which explains the trend shown by the dashed black line in FIG. 1D.

The distinct, evenly spaced surface potential steps demonstrated in the devices of the invention can switch between N+1 local combinations (with N the number of interfaces) and are controlled by the direction of the interlayer shift in each interface. Therefore, devices of the invention further allow for novel technological concepts such as:
1. Photovoltaic cells: by absorbing light, the non-polar layered structures are known to generate electron-hole pairs that eventually recombine without generating finite current unless an external voltage bias is applied between the bottom/surface of the structure. The polar structures demonstrated here allow photovoltaic devices that can convert the light to electric currents due to the intrinsic polarization and without applying external bias. Moreover, the direction of the photocurrent can be switched by switching the internal polarization orientation with the interlayer shear.
2. Electro-mechanical generators: the mechanical shear motion generates out-of-plane polarization and charge transfer between consecutive layers. Thus, a mechanical motion of one inter-atomic space is converted to a charge current in the up/down direction depending on the in-plane interlayer shift direction. Moreover, a continuous motion along a fixed in-plane direction by more than one interatomic spacing will switch the current direction up/down with each extra step, thus, generating an alternating current.
3. Dense information manipulation and storage: unlike common computing and storing devices that switch between only two distinct states, the technology disclosed herein can switch between N+1 distinct states in each location. With a density of one state per each extra layer (thickness ˜0.6 nm in hexagonal TMDs, and ˜0.3 nm in hexagonal Boron-Nitride). This is the highest density of separated states per structure thickness reported to date.
4. Motion detection technologies: the measurement of the local potential or conductivity or optical response of the structure detects shifts between any two layers due to shear stress with a shift resolution of an inter-atomic spacing (˜0.19/0.12 nm for hexagonal TMDs/hexagonal boron nitride respectively).
5. Opto-mechanical modulators. Each interlayer shift in the multi-layer structure changes the multi-layer structure and its optical response. Thus, controlling the shift by mechanical shear stress or an external bias, as shown in the devices reported here, can modulate the optical response.
6. Electronic devices that combine in-plane conductivity and internal out-of-plane polarization. For example, the ferroelectric tunnel junctions in current technologies use the internal polarization of insulating ferroelectric material as a spacer between other conducting or semiconducting materials. Combining the different materials as required into one device poses many practical and technological challenges. The structures demonstrated herein use the hexagonal diatomic material as both the internally polarized spacer and the conducting electrodes without combining additional materials. This structure of metallic/semiconducting electrodes made of conducting materials that encapsulate non-conducting polar materials is common in many technologies, including the Photovoltaic cells discussed above. The devices demonstrated here are made of 2D materials only.
7. Devices, as discussed above, use the in-plane conductivity to detect the polarization state and the stacking configurations without the need to measure the surface potential by an additional instrument or material.

The invention further provides a process for constructing a multilayer structure of the invention, the process comprising orienting any two stacked layers of one or more 2D materials into a stacked substantially parallel lattice orientation (namely into a parallel orientation or a slightly angled orientation), wherein one or more of the layers of the structure are formed of a doped 2D material.

The invention further provides a process for constructing a multilayer structure of the invention, the process comprising orienting any two stacked layers of one or more 2D materials into a stacked substantially parallel lattice orientation (namely into a parallel orientation or a slightly angled orientation), to obtain the multilayer structure and exposing said structure to electrostatic doping to induce in-plane conductivity.

The orientation of any two stacked layers of doped/undoped materials may be achievable by a variety of methodologies. In some embodiments, orientation is achieved by positioning two or more layers or flakes of the material atop of each other in a substantially parallel lattice orientation as disclosed herein. Reference to “any two stacked material layers” is to any two material layers that are immediately on top of each other, not separated by a further layer. The layers are substantially parallel, namely they may be purely parallel or slightly parallel, exhibiting a minor deviation from parallel orientation.

This process may be employed on any 2D material as disclosed herein.

In some embodiments, the process comprises layering two or more flakes of a doped diatomic hexagonal material such that a stacked multilayer material is obtained wherein each layer in the multilayer material is in a substantially parallel lattice orientation.

In some embodiments, the process comprising depositing a layer of a doped diatomic hexagonal material on top a layer of same doped or undoped diatomic hexagonal material such that a stacked multilayer material is obtained wherein each layer in the multilayer material is in a parallel lattice orientation.

In some embodiments, the process comprising
providing a doped diatomic hexagonal multilayer crystal or material,
separating layers making up the crystal or material into separate layers, and
stacking at least one of the separated layers on top of another, such that an internal interfacial electric field normal to the layers plane of the material is formed at an interface between the two stacked material layers, and in-plane conductivity is achieved.

In other embodiments, the process comprising
providing two or more flakes of a doped diatomic hexagonal material;
stacking the two or more flakes into a multilayer material, wherein each layer in the multilayer material is in a parallel lattice orientation.

In some embodiments, the two or more flakes are obtained from exfoliating layers of a diatomic hexagonal multilayer crystal or material and doping same, or by exfoliating layers of a doped diatomic hexagonal multilayer crystal or material.

In some embodiments, the number of layers in the multilayer material is at least two.

In some embodiments, the number of layers in the multilayer material is two or three or more.

In some embodiments, the number of polarization states is equal to the number of internal interfaces between stacked layers in the multilayer material.

The invention further provides:

A multilayer material or structure comprising two or more stacked layers of a 2D material, wherein at least one of said two or more layers of a 2D material is a layer of a doped 2D material, and wherein the multilayer material or structure exhibiting in-plane conductivity, and an out-of-plane switchable polarization.

A multilayer material having a plurality of out-of-plane switchable polarization states, the multilayer material comprising two or more stacked layers of a 2D material, wherein at least one of the layers formed of the 2D material is doped with charge carriers or holes (electrons or holes) that are (substantially) evenly distributed in the material layer(s), thereby inducing in-plane conductivity.

A conductive material comprising a stacked multilayer of two or more layers of a 2D material, at least one of which being a layer of a doped 2D material, each layer of the two or more layers of the 2D material having a global (cumulative) polarization pointing in a direction normal to a direction of conductivity.

A material in a form of a multilayer of two or more layers of a doped 2D material exhibiting in-plane conductivity, wherein each layer having a polarization pointing in a direction normal to the multilayer plane and opposite to the direction of polarization of any adjacent layer.

In some embodiments of any of the multilayer material according to the invention, each layer in the multilayer material is in a (substantially) parallel lattice orientation.

In some embodiments of any of the multilayer material according to the invention, each of the material layers is formed of a 2D semiconductor material.

In some embodiments of any of the multilayer material according to the invention, the 2D material is a diatomic hexagonal material.

In some embodiments of any of the multilayer material according to the invention, the diatomic hexagonal material is selected from hexagonal-boron-nitride (h-BN), transition-metal-dichalcogenides (TMD), hexagonal-aluminum-nitride (h-AlN), hexagonal-zinc-oxide (h-ZnO), and hexagonal-gallium-nitride (h-GaN).

In some embodiments of any of the multilayer material according to the invention, the 2D material is a transition-metal-dichalcogenides (TMD) selected from MoS₂, WS₂, MoSe₂ and WSe₂.

Also provided is a conductive stacked multilayer diatomic hexagonal material or a conductive stacked multilayer structure formed by orienting any two stacked layers of a doped diatomic hexagonal material into a stacked (substantially) parallel lattice orientation to induce internal interfacial electric field normal to the layers plane at an interface between the two stacked material layers and in-plane conductivity.

In some embodiments of any of the multilayer material according to the invention, the doped multilayer is formed by chemical doping of the 2D materials prior to forming the multilayer structure.

In some embodiments of any of the multilayer material according to the invention, the doped multilayer is formed by electrostatic doping of a preformed multilayer.

In some embodiments of any of the multilayer material according to the invention, the material is n-doped.

In some embodiments of any of the multilayer material according to the invention, the material is p-doped.

In some embodiments of any of the multilayer material according to the invention, the material having a charge density of at least 10¹⁰ cm^{31 2}.

In some embodiments of any of the multilayer material according to the invention, the material having a charge density between 10¹⁰ cm⁻² and 10¹⁴ cm⁻² or between 10¹² cm⁻² and 10¹⁴ cm⁻² or between 10¹³ cm⁻² and 10¹⁴ cm⁻².

In some embodiments of any of the multilayer material according to the invention, the material comprising two or more stacked layers of a 2D material exhibiting out-of-plane switchable polarization and comprising free charge carriers of a density that is at least 10¹⁰ cm⁻² evenly distributed in the multilayer.

In some embodiments of any of the multilayer material according to the invention, the material comprising two or more layers of a TMD material stacked in a substantially parallel lattice orientation and exhibiting out-of-plane switchable polarization and comprising free electrons or holes of a density that is at least 10¹⁰ cm⁻² evenly distributed in the multilayer.

Also provided is a use of a material according to the invention in constructing or manufacturing an electronic, optical or photoelectronic device.

Also provided is a device comprising a multilayer structure comprising two or more stacked layers of a 2D material, wherein at least one of said two or more layers of a 2D material is a layer of a doped 2D material, and wherein the multilayer material or structure exhibiting in-plane conductivity, and an out-of-plane switchable polarization.

Further provided is a multi-switch polarization device having in-plane conductivity, the device comprising a plurality of out-of-plane switchable polarization states, the multilayer material comprising two or more stacked layers of a 2D material, wherein at least one of the layers formed of the 2D material is doped with charge carriers or holes (electrons or holes) that are (substantially) evenly distributed in the material layer(s).

In some embodiments of any of the devices according to the invention, the device comprises a pair of electrodes, each of said electrodes being positioned at an edge of the layers of the multilayer material.

In some embodiments of any of the devices according to the invention, the device comprises a top electrode and a bottom electrode.

In some embodiments of any of the devices according to the invention, the device is selected from non-volatile memory devices, MEMS, photovoltaic cells, field effect transistors, memristors, and polar diodes.

Further provided is a device implementing a material according to the invention.

In some embodiments of any of the devices according to the invention, the device comprising two or three or more layers of one or more transition metal dichalcogenide (TMD), wherein the layers are artificially stacked in a parallel lattice orientation and encapsulated by thin flakes of a non-polar hexagonal boron nitride (h-BN), placed atop a graphite or gold metallic electrode.

In some embodiments of any of the devices according to the invention, the device is a photovoltaic cell, an electro-mechanical generator, a dense information manipulation and storage device, a motion detection device, an opto-mechanical modulator, or an electronic device combining in-plane conductivity and internal out-of-plane polarization.

In some embodiments of any of the devices according to the invention, the device is a photovoltaic device.

Also provided is a photovoltaic device comprising a multi-switch polarization arrangement having in-plane conductivity, the arrangement being a multilayer stack of two or more layers of at least one 2D material, wherein at least one of the layers formed of the 2D material is doped with charge carriers (electrons or holes) that are (substantially) evenly distributed in the material layer(s), the device comprising a pair of electrodes positioned at the stacked layers edges and optionally a top electrode and a bottom electrode.

Further provided is a process for constructing a multilayer structure or material according to the invention, the process comprising orienting any two stacked layers of one or more 2D materials into a stacked (substantially) parallel lattice orientation, wherein one or more of the layers of the structure are formed of a doped 2D material.

Also provided is a process for constructing a multilayer structure according to any one of claims 1 to 4, the process comprising orienting any two stacked layers of one or more 2D materials into a stacked (substantially) parallel lattice orientation, to obtain the multilayer structure and exposing said structure to electrostatic doping to induce in-plane conductivity.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIGS. 1A-F: Excess charge distribution calculations for polar bilayers of MoS₂ (left panels) and Wse₂ (right panels). (A,B) Laterally averaged excess carrier density profiles of the undoped bilayers, ρ₀^{ex}(z) (dashed black line), defined as the density of the bilayer stack after subtracting the superposition charge density of two isolated layers. Doping-induced variations in the excess carrier density, Δρ^{ex}(z), for different hole densities are represented by the solid lines (C,D). The results for MoS₂ are divided by 10 for clarity of the representation. (C,D) Doping induced antisymmetric part of the charge carrier density variation profiles defined as Δρ^{ex}(z)−Δρ^{ex}(−z), where z=0 is set at the bilayer center for several doping densities. (E,F) Band structures of the undoped bilayer systems, colored according to the projection of the corresponding crystal momentum state on the top (light grey) and bottom (black) layers (see text). K momentum states split into layer-specific bands (prominent grey\black) that resemble the dashed black bands of a monolayer, only separated by [symbol] A larger splitting due to strong interlayer-delocalization (designated by dark grey) appears for valence Γ and conduction Q states.

FIGS. 2A-B: (A) DFT calculations as in FIG. 1, for relaxed multilayers of 3R-MoS2, 3R-WSe2 and 3R-BN. The pristine BN result suggests potential accumulations as high as 4V, significantly larger than the TMD crystals. The dashed lines represent the band gaps of the periodic structures. (B) Measured average surface potential as a function of the number of layers N for 2 representatives 3R MoS₂ flakes, each containing regions of various thicknesses (triangles). DFT calculations of the total potential difference across separate 3R crystals containing 2-20 layers with co-polarized interfaces (empty squares). A Schrodinger-Poisson equation solution of the surface potential for the same structures while considering a finite doping level of 13.5e−10 cm⁻² (circles).

FIGS. 3A-E: Multiple polarization states in Wse₂ multi-layers. A. Schematic illustration of the Kelvin probe force microscopy setup including a multi-layered TMD structure (lightest grey), encapsulated between h-BN layers (dark grey) that are placed on a graphitic or gold (black) gate (V_{g}) electrode lying atop a silicon oxide substrate (bottom dark grey). B. Electric potential map at the Wse₂ tri-layer surface. The dashed white lines mark borders between regions consisting of single and two active interfaces. Arrows denote the out-of-plane polarization orientation in five domains with different stacking configurations. C. Typical line cuts of the lateral potential drop across domain walls separating single (solid) and two (dashed) active interface regions (see Fig. S1f and panel b). Line cuts crossing domain walls that separate smaller domains are illustrated by the solid and dashed lines in panel A. The stacking configurations at the corresponding interfaces (shown schematically for the bilayer) are marked aside each potential step, with the corresponding interface polarizations marked by black arrows. D. Calculated laterally-averaged vertical potential profile along an ABC stacked trilayer with co-oriented (black arrows) interfacial polarization. E. Calculated potential difference across a multi-layer Wse₂ structure compared to the experiment. The potential accumulates linearly with each extra layer for ABC stacking (full dots) and remains unaltered for anti-parallel AA′ stacking (empty squares).

FIGS. 4A-F: Multi-polarization states in naturally-grown 3R MoS₂. A-D. Topography (A,C) and surface potential (B,D) maps of two typical flakes composed of 2-7, and 7-13, respectively. The potential is measured relative to the value above an ABA stacked tri-layer region. E. Line cuts, as marked in A-B, showing the flake thickness (empty squares, left axis) and surface potential (full circles, right axis). The horizontal grids show evenly-spaced steps. F. Surface potential values and excess number of active interfaces (N_{↑}−N_{↓}) above different positions (as marked in a-d) versus the number of layers at each point. The dashed black line connects points of the fully co-aligned polar interfaces, where the symbols correspond to those appearing in A, B and E. Other points (with symbols corresponding to those appearing in panels C and D) show fixed, evenly spaces values corresponding to multi-polarization configurations. For example, the four values measured above 7 layers with 6 active interfaces correspond to the 6_{↓}, 5_{↓}1_{↑}, 3_{↓}3_{↑}, and 2_{↓}4_{↑} combinations. Calculated maximal polarization values are indicated by the full squares.

FIGS. 5A-D: Effect of gate bias on the polarization. A-C. Surface potential maps obtained for bilayer MoS₂ under different gate biases. The center of the scale bar in each map is set to the corresponding average potential, V_{avg}, as indicated in the respective panel. The color scale is centered at the average potential of the two polarizations, V_{avg}. D. Potential drop ΔV_{KP} across domains of opposite polarization (see FIG. 4C), as a function of the external displacement field D and the corresponding 2D carrier density (lower/upper horizontal axis). Data from one MoS₂ sample (stars) and two different WSe₂ samples (triangles and circles) are compared to the calculated 2Δ∅ values (solid, dashed lines, respectively).

FIGS. 6A-D: Doping and depolarization measurements. (A-C) Examples of surface potential maps obtained from a parallel WSe₂ bilayer under several gate biases V_{g} (Device 3). Note the domain wall motion at high doping density (C) that extends bright areas over dark domains. (D) The average KP potential of the TMD bilayers, V_{avg}, as a function of the applied gate potential, V_{g}.

FIGS. 7A-F: Further device characterization. (A-B) Optical microscope image of a typical device. Two circuit configurations of gating and KPFM measurement are illustrated. (C) The electric current along the MoS₂ bilayers is measured versus the source-drain bias (V_{sd}) and plotted for several fixed gate voltages (V_{g}) at room temperature. (D-E) Simultaneous measurement of topography and KPFM maps for a tri-layer WSe₂ structure (also shown in FIG. 4 in the main text). The dark regions in the topography map indicate a crack in one of the layers, separating regions of trilayers with one and two active interfaces. (E-F) Examples of ferroelectric-like coupling between the two active interfaces in large-area domains. The ↑↓ (ABA, neutral color, 0.2V) domains cover a smaller area than the ↓↓ (CBA, dark, 0.02V) domains (circumscribed in white). The same is found for ↑↑ (ABC, bright, 0.3V) regions marked in black. The solid grey and dashed lines in (F) mark the line cut position of the data shown in the main-text, FIG. 5C.

FIG. 8: Potential and charge density profiles of bilayer WSe₂. Difference between bilayer and isolated monolayer plane-averaged potential (solid) and charge density (dashed) for an AB stacked WSe₂. The dashed lines represent the vertical location of the ions. The origin of the horizontal axis is set to the midpoint between the layers.

FIGS. 9A-C: Convergence tests. Convergence tests of the binding energy (black curve, left vertical axis) and electrostatic potential difference (grey curve, right vertical axis) of a WSe₂ bilayer (same structure as in FIG. 8) as a function of: (A) vacuum size; (B) energy cutoff, and (C) number of k-points.

FIGS. 10A-B: Potential and charge density profiles for WSe₂ and MoS₂ bilayer. Difference between bilayer and isolated monolayer plane-averaged potential (solid) and charge density (dashed) for AB stacked (A) WSe₂ and (B) MoS₂ bilayers. The vertical dashed lines represent the vertical location of the ions. The origin of the horizontal axis is set to the midpoint between the layers.

FIGS. 11A-F: Convergence tests. Convergence tests of the binding energy (black curve, left vertical axis) and electrostatic potential difference (grey curve, right vertical axis) of WSe₂ (top panels) and MoS₂ (bottom panels) bilayers (same structures as in FIG. 10) as a function of (A, D) vacuum size; (B, E) energy cutoff, and (C, F) number of k-points.

FIG. 12: Effect of doping on the interlayer potential drop. The potential drop as a function of electron (n, filled squares) and hole (p, empty circles) doping density for AB stacked bilayer WSe₂ (grey) and MoS₂ (black). The doping is introduced via the metal pseudo nuclei.

FIGS. 13A-F: Band structure and Fermi level variations with doping charge density. (A,D) The band structures of undoped (black), n-doped (dark grey), and p-doped (light grey) WSe₂ (A) and MoS₂ (D). For WSe₂ (MoS₂) the n-doped and p-doped band-structures are plotted for a charge density of Δn_{2D}=∓1.1×10¹³ cm⁻² (∓9.3×10¹³ cm⁻²), respectively. The origins of the vertical axes are set to the topmost Γ-point valence band energy (E_{Γ-VBM}). (B, E) The variation of the difference between the topmost K and Γ valence band energies as a function of doping density for (B) WSe₂ and (E) MoS₂. Results are presented with respect to the energy difference obtained for the undoped system: ΔE=[E_{K-VBM}−E_{Γ-VBM}]_{doped}−[E_{K-VBM}−E_{Γ-VBM}]_{undoped}. (C, F) The Fermi level position of (C) WSe₂ and (F) MoS₂ as a function of n-doping (grey) and p-doping (black) charge densities. The origins of vertical axes are set to the conduction band minimum energy for n-doping and the valence band maximum energy for p-doping. The doping is introduced via the metal pseudo nuclei.

FIGS. 14A-B: Comparison of different doping schemes. The polarization as a function of n-doping (grey) and p-doping (black) charge density for (A) WSe₂ and (B) MoS₂. Different doping schemes are applied including: only metal ions (filled squares), only chalcogen ions (open circles), or all ion doping (open triangle). For WSe₂, the W ion doping charge excess values were ε=10⁻⁴, 2×10⁻⁴, 5×10⁻⁴, 8×10⁻⁴, 10⁻³, 2×10⁻³, 5×10⁻³, 8×10⁻³, 0.01; the Se ion doping charge values were ε=5×10⁻⁵, 10⁻⁴, 2.5×10⁻⁴, 4×10⁻⁴, 5×10⁻⁴, 10⁻³, 2.5×10⁻³, 4×10⁻³, 0.005; and the all ion doping charge excess values used were ε=3.3×10⁻⁵, 6.6×10⁻⁵, 1.6×10⁻⁴, 2.6×10⁻⁴, 3.3×10⁻⁴, 6.6×10⁻⁴, 1.6×10⁻³, 2.6×10⁻³, 0.0033. The electron configuration of Se was given by [Ar]3d¹⁰4s²4p^{4±ε}, and the corresponding nuclear charge was Z=34±ε. For MoS₂, the Mo ion doping charge excess values were ε=10⁻⁴, 10⁻³, 2×10⁻³, 5×10⁻³, 8×10⁻³, 0.01, 0.02, 0.03, 0.04; the S ion doping charge excess values were ε=5×10⁻⁵, 5×10⁻⁴, 10⁻³, 2.5×10⁻³, 4×10⁻⁴, 0.005, 0.01, 0.015, 0.02; and the all ion doping charge excess values used were ε=3.3×10⁻⁵, 3.3×10⁻⁴, 6.6×10⁻⁴, 1.6×10⁻³, 2.6×10⁻³, 3.3×10⁻³, 6.6×10⁻³, 0.01, 0.013. The electron configuration of S was given by [Ne]3s²3p^{4±ε}, and the corresponding nuclear charge was Z=16±ε.

FIGS. 15A-B: Effect of polarization on the band structure. The band structures of (A) WSe₂ and (B) MoS₂ bilayers at their anti-parallel AA′ (solid black curve) and parallel AB (dashed grey curve) stacking modes.

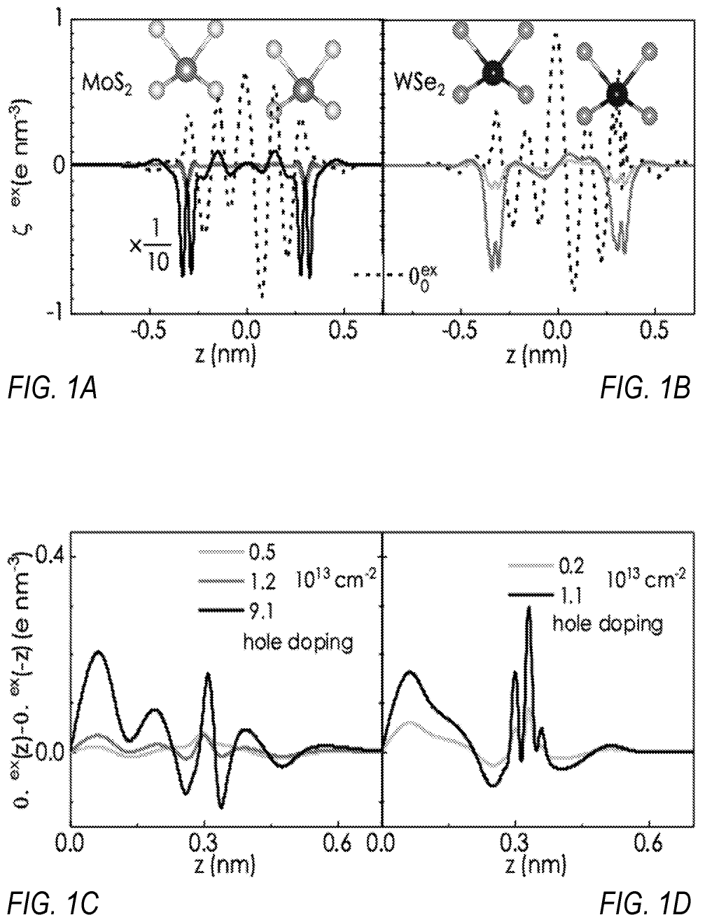

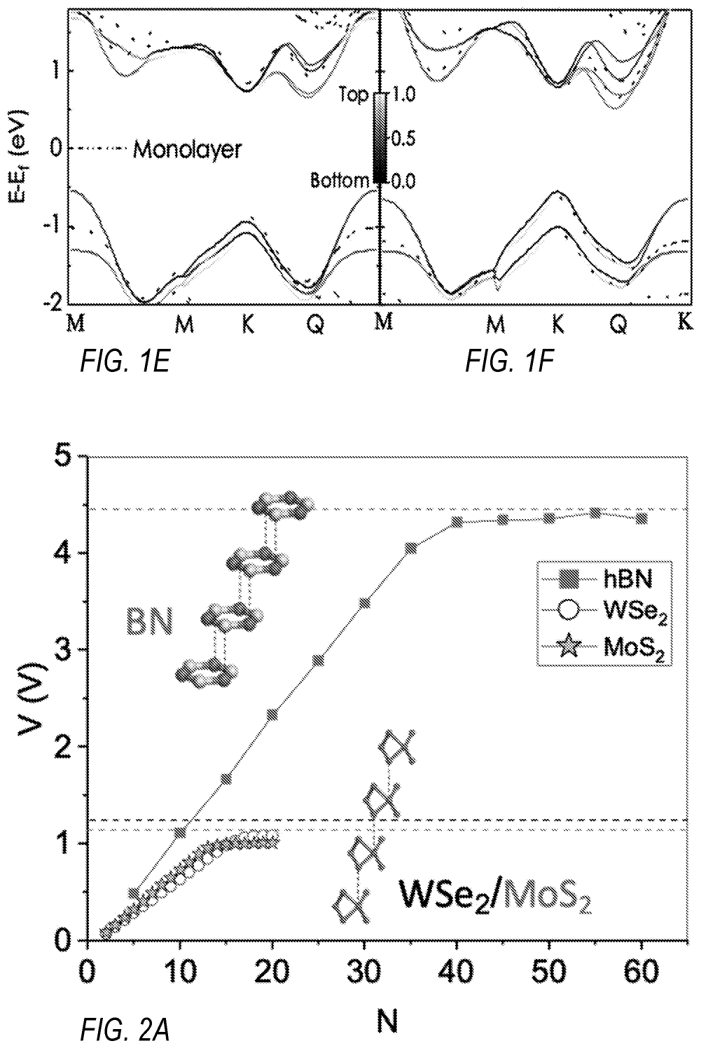

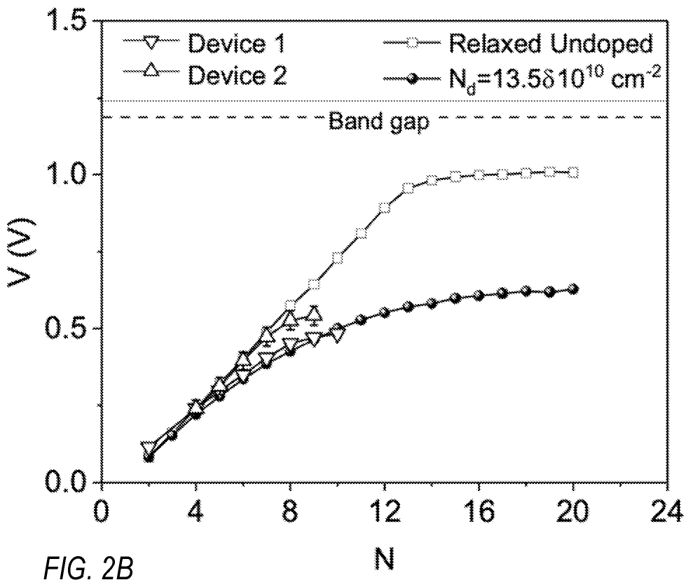

### DETAILED DESCRIPTION OF EMBODIMENTS

As disclosed herein, the inventors now demonstrate stacked 2D layers that support robust interfacial polarization which features three unique characteristics: (i) it supports polarization as high as ˜0.5 pC/m per interface; (ii) it exhibits distinct and switchable multiple polarization configurations; and (iii) it sustains charge carrier densities up to 10¹⁴ cm⁻², a computational prediction that is confirmed by the experiments disclosed herein for charge carrier densities as high as 10¹³ cm⁻². The coexistence of polarization and conductivity is attributed to the interfacial localization of the polarization and the excess charge carriers delocalization on both layers, which inhibits strong depolarization fields. Notably, the measured polarization and density values are nearly ten times larger than those found for non-hexagonal TMDs to date and may support rich correlated electronic phases. The cumulative distinct multi-polar ladder of states reported here thus paves the way to bottom-up construction of 3D multi-ferroic structures out of well-defined 2D building blocks in a controllable, position-and orientation-specific manner.

### Materials and Methods

### Device Fabrication

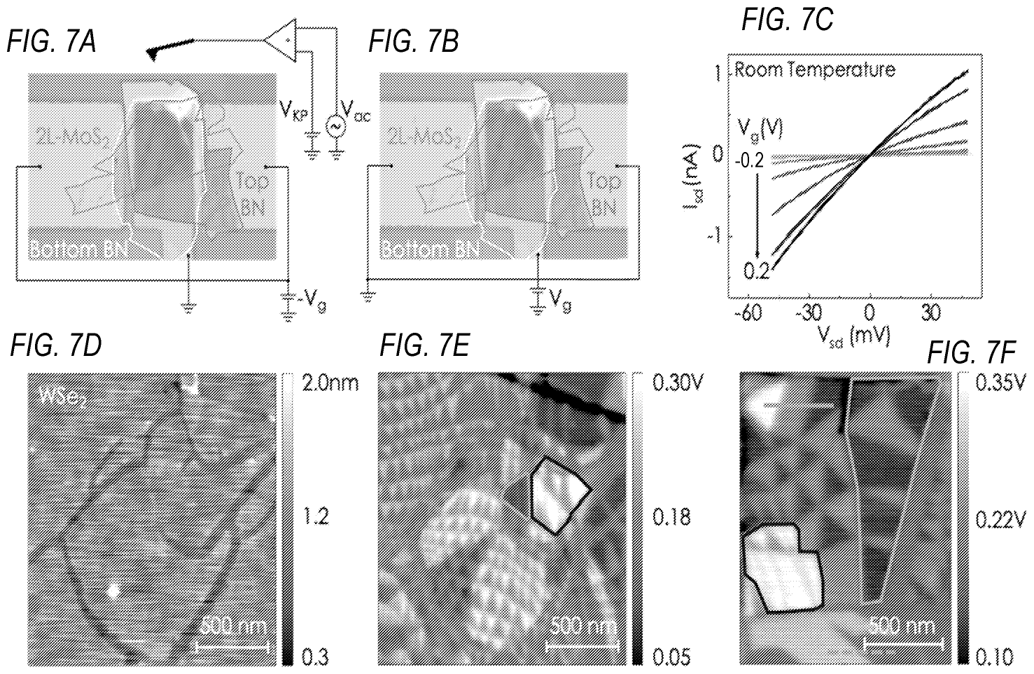

h-BN flakes of various thicknesses were exfoliated onto a Si/SiO₂ substrate. MoS₂ and WSe₂, obtained from HQ Graphene, were exfoliated onto polydimethylsiloxane (PDMS). Large single-layer flakes (˜20 μm or more) of transition metal dichalcogenides (TMDs) were identified using optical contrast. h-BN flakes were picked up from the substrate and placed on few-layered graphene or predesigned gold electrodes (FIG. 7A). Subsequently, parallel bilayers of TMDs were prepared on the h-BN surface using the ‘tear and stack’ technique. In this process, a fragment of a chosen TMD flake is first stamped on h-BN, followed by successive stacking of the remaining flake on it. The entire stack is then encapsulated with another h-BN flake. The bottom graphene or gold substrate acts as a reference electrode for Kelvin probe force microscopy (KPFM) measurements and as a gate electrode. In the tri-layer measurements (without doping), the stack was placed directly on the conducting electrode without the bottom h-BN.

TABLE 1
Details of devices according to some
embodiments of the invention.

| | | h-BN spacer |
|---|---|---|
| Device Name | Electrode | thickness (nm) |
| Dev 1: MoS₂ | Au | 6.3 |
| Dev 2: WSe₂ | Few layer graphene | 12 |
| Dev 3: WSe₂ | Au | 5.1 |

### AFM Measurements

Topography and KPFM measurements were acquired simultaneously, using Park System NX10 AFM in non-contact scanning mode. The electrostatic signal was measured at a side-band frequency using a built-in lock-in amplifier. A PointProbe Plus Electrostatic Force Microscopy (PPP-EFM) n-doped tips with a conductive coating was used. The mechanical resonance frequency of the tips was ˜75 kHz and the force constant was 3 N/m. The cantilever oscillated mechanically with an amplitude ranging from 20 to 5 nm. In several experiments, the average height above the surface, h, was controlled via a two-pass measurement. The first pass records the topography, whereas in the second pass the tip follows the same scan line with a predefined lift (typically 4-5 nm) and measures the KPFM signal. The cantilever was excited with an AC voltage to perform KPFM measurements, with an amplitude of 1.5-4 V and a frequency of 2-4 kHz. In the closed-loop measurements, the DC voltage was controlled by a bias servo to obtain the surface potential. Images were acquired using the Park SmartScan software and the data analyzed with Gwyddion program.

### Finite Ferroelectric-Like Coupling of Two Active Interfaces

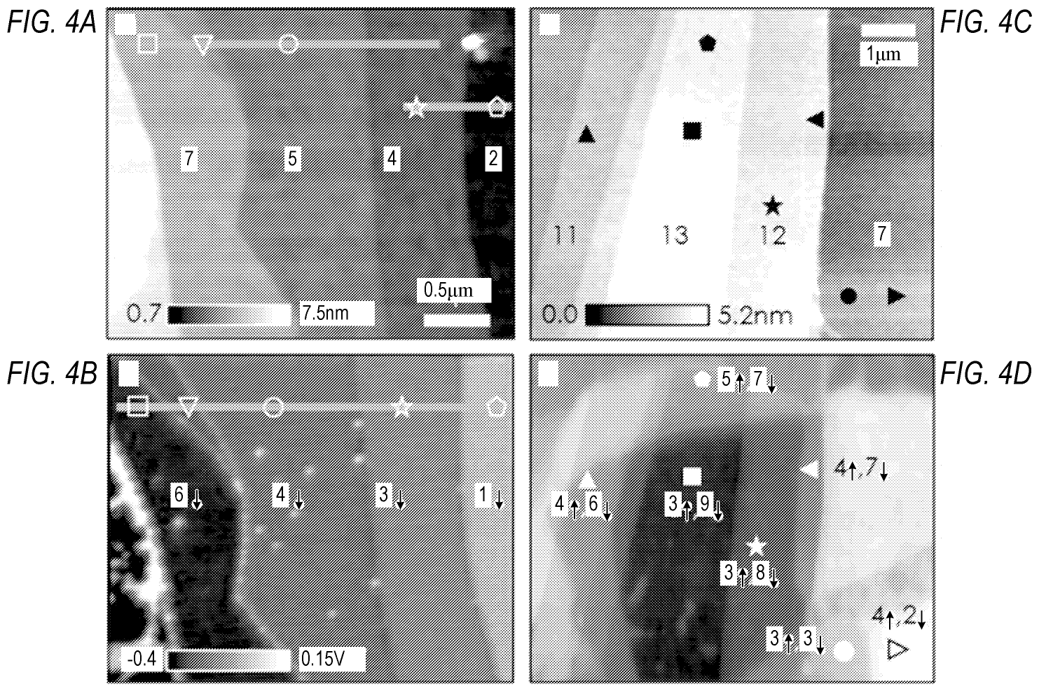

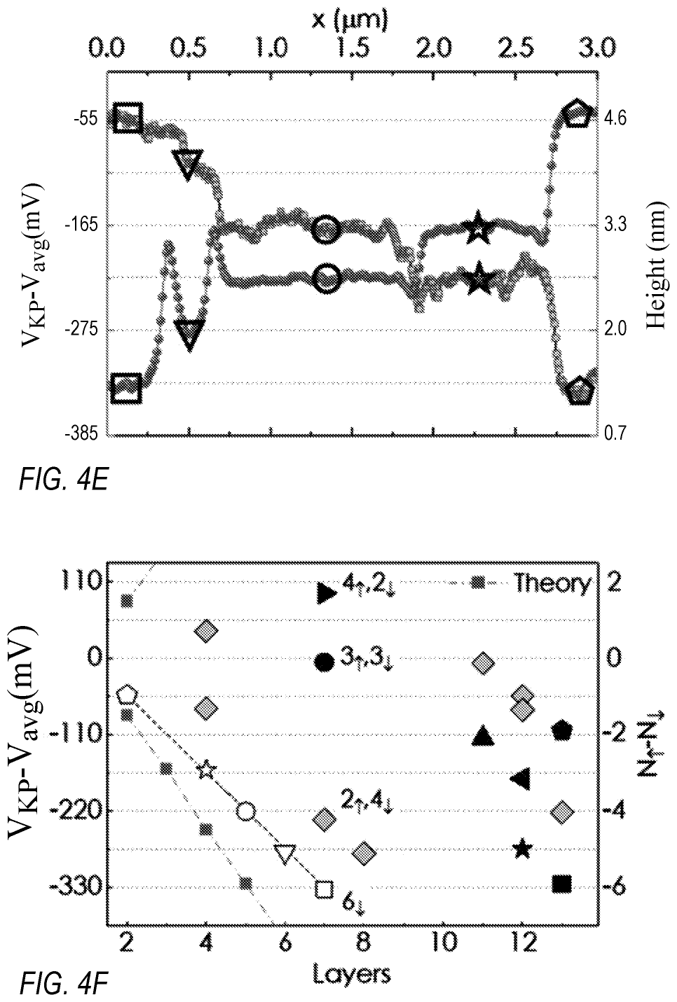

While the internal electric fields are mostly confined to the interfacial volume, as discussed in the main text, we find indications of finite coupling between adjacent regions of two active interfaces structures. This is achieved by comparing the average area coverage of co-aligned (ABC/CBA) and anti-aligned (ABA) domains (FIGS. 7E-F). The higher adhesion phase naturally expands on the expense of other stacking configurations. Indeed, we find that regions in the map of large area domains show a clear preference for ABC or CBA stackings with ↑↑ or ↓↓ (bright or dark) polarization, respectively, at the expense of the anti-aligned ABA and BAB domains (with neutral-color) of ↑↓ or ↓↑ polarization, respectively. A close look at two active interface regions with smaller domains (outside the marks) also shows a reduced area of the neutral domains even away from the physical edge of the layers (although the area difference here is minor). Recently, we reported a similar behavior in a single active interface system of parallel h-BN bilayers, where domain wall sliding in response to an externally applied electric field promoted larger domains that align with the external field at the expense of the anti-aligned configuration (see also FIGS. 4A-C). The dynamics of this phenomenon is governed by the loss of adhesion energy in the domain wall network and the pinning from the disorder at the interface. The internal out-of-plane coupling reported here (with no external field) reveals a more stable ferroelectric coupling (ABCABC . . . ) in comparison to the antiferroelectric order in the Bernal (ABAB . . . ) configuration.

### Doping and De-Polarization Measurements

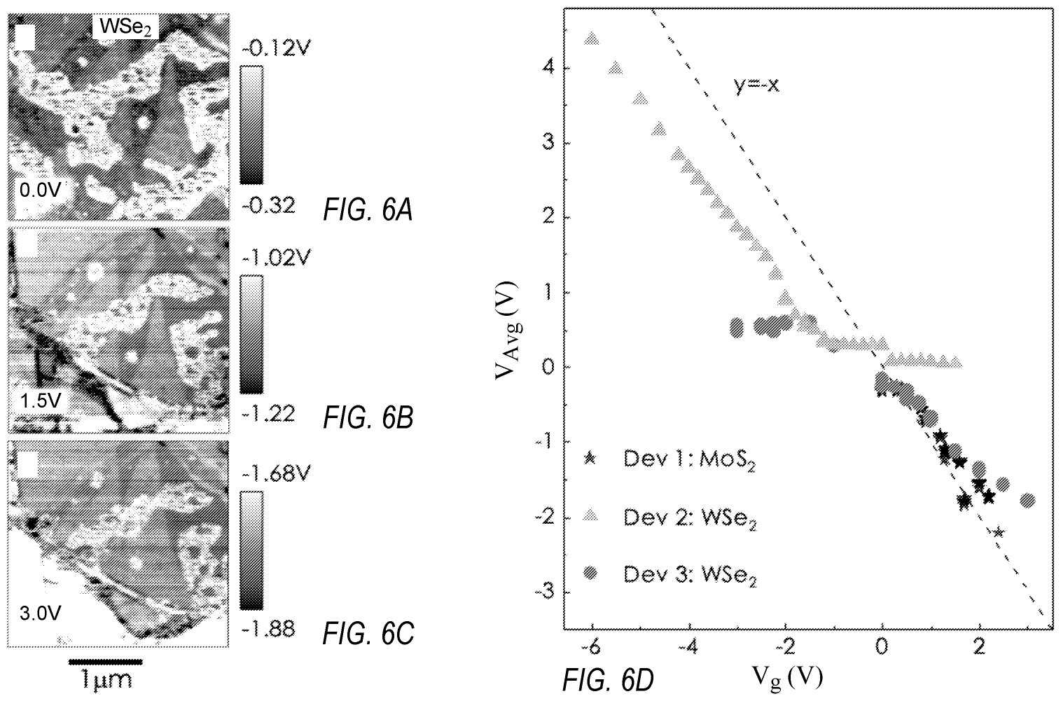

A precise measurement of the out-of-plane polarization at the high doping limit is challenging due to the KPFM signal sensitivity to long-range coulomb forces. The latter interacts with the tip's cantilever and cone rather than its local apex only. While the side-band measurement mode overcomes this challenge to provide quantitative information at zero gate bias, its reliability drops as the external potential on the gate electrode and correspondingly the doping charge density on the TMD increase. Crucially, this measurement limitation can only underestimate (by averaging out) the local potential drop, ΔV_{KP}, between domains and its corresponding polarization magnitude. To minimize this underestimation, we used two complementary gating schemes, where either the sample potential is grounded, and the gold electrode is biased or vice versa (FIGS. 7B and 7A a respectively). Data shown in the main text and in the configuration of FIG. 7A. We also focused on domains located next to the electrode's edges (while placing the cantilever outside them) and controlled the potential on the global silicon substrate independently. Additional limitations arise from the motion of domain walls at high charge doping and displacement fields, surface chemical adsorption, and surface degradation (see FIGS. 6A-C). The latter hinders our quantitative analysis even with a very thin gate dielectric (down to 5 nm thick), where the maximum doping level (at the h-BN breakdown electric field) is reached at moderate gate potentials.

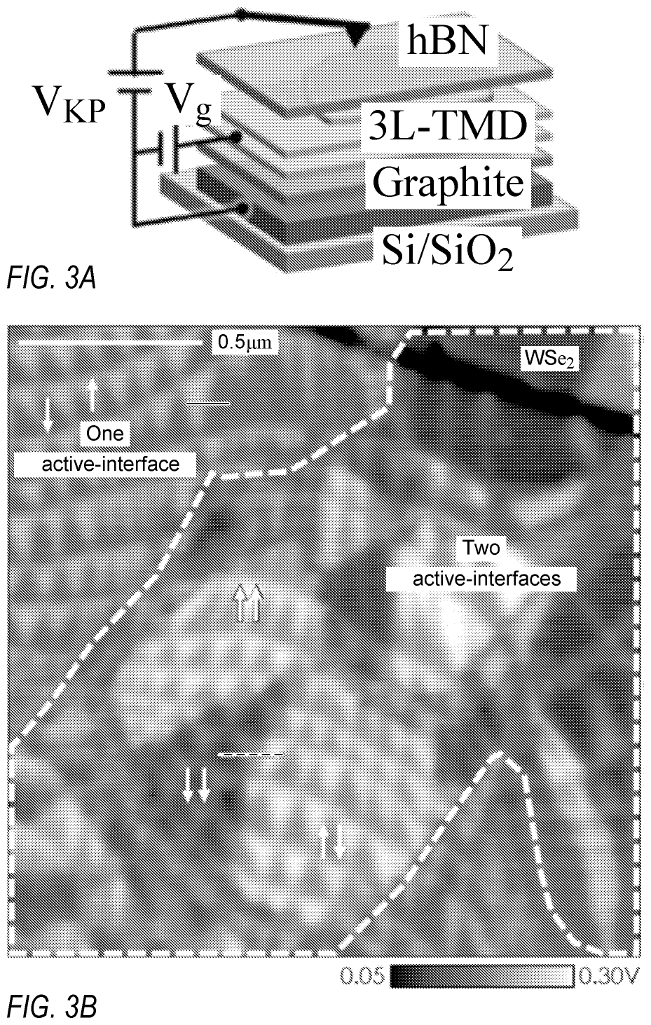

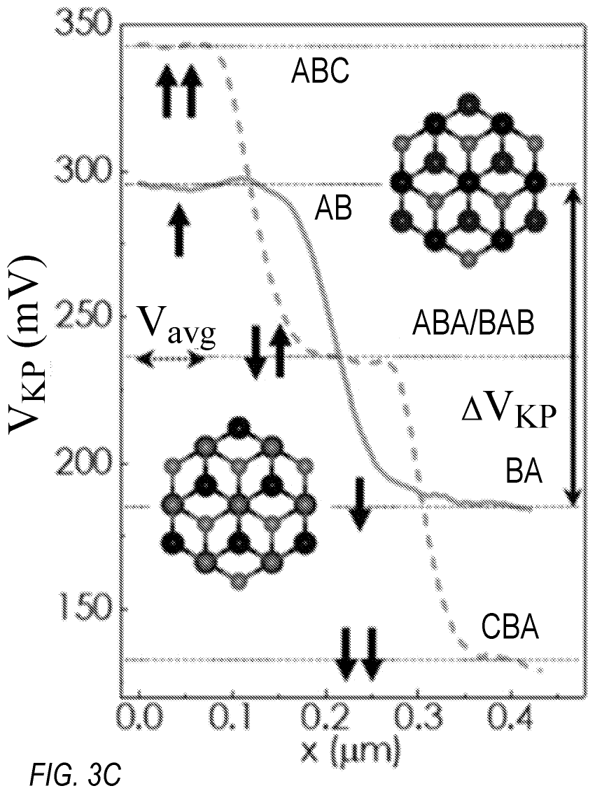

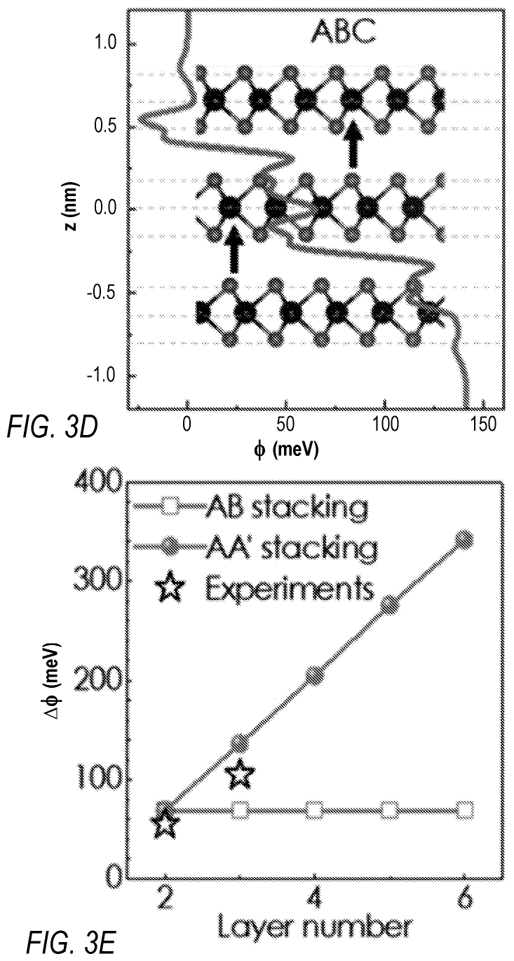

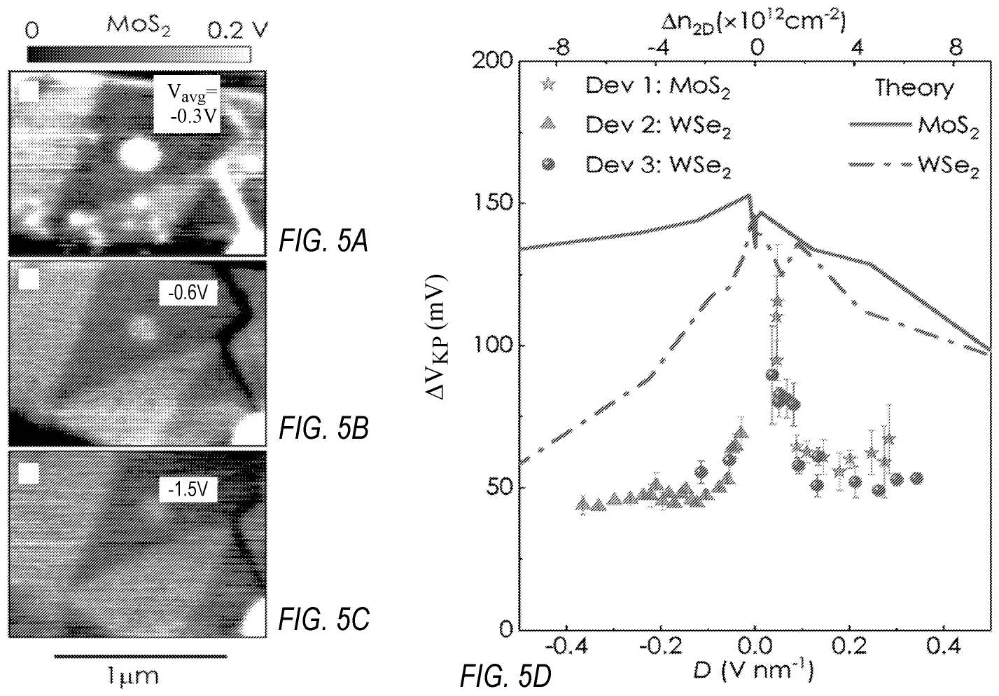

Lastly, localized defect states at the host crystals may reduce the occupation of delocalized states by the gate bias. This may result in some overestimate of the precise doping, if extracted from the geometric capacitance only. To eliminate this overestimation, we extracted the doping density in FIG. 5B from the change in the average potential (V_{avg}), measured on oppositely polarized domains (as marked in FIG. 3C), rather than directly from the applied V_{g}. V_{avg} grows with V_{g} beyond some threshold value, and in one direction only for each particular sample (FIG. 6D). We attribute this behavior to unpinning of the Fermi-level from gap states associated with native dopants in each sample. The latter seems to prevent achieving electron and hole doping in the same sample. Importantly, V_{avg} is only sensitive to the mobile charge density that accumulates to screen the bottom electrode, regardless of internal properties of the electrodes such as localized defect states, Schottky barriers, or quantum capacitance. The deviation from the ideal V_{avg}=−V_{g} (dashed black) slope at high |V_{avg}| is attributed to the underestimation of the local KPFM signal in case of large doping levels and spatially alternating potentials at the edges of the electrodes, as discussed above. Altogether, the measurements in FIG. 5D provide an underestimation of the polarization magnitude and the mobile charge density.

### Calculation of WSe₂ Polarization

The electrostatic potential profile along the normal direction of AB stacked few-layered WSe₂ is presented in FIG. 3. To obtain this profile, the Perdew-Burke-Ernzerhof (PBE) generalized-gradient exchange-correlation density functional approximation was used, augmented by the Grimme-D3 dispersion correction with Becke-Johnson (BJ) damping as implemented in the Vienna Ab-initio Simulation Package (VASP). The core electrons of the W and Se atoms were treated via the projector augmented wave (PAW) approach. Spin-orbit interactions were included. This level of theory was recently successfully used to calculate the polarization of transition metal dichalcogenide (TMD) bilayers.

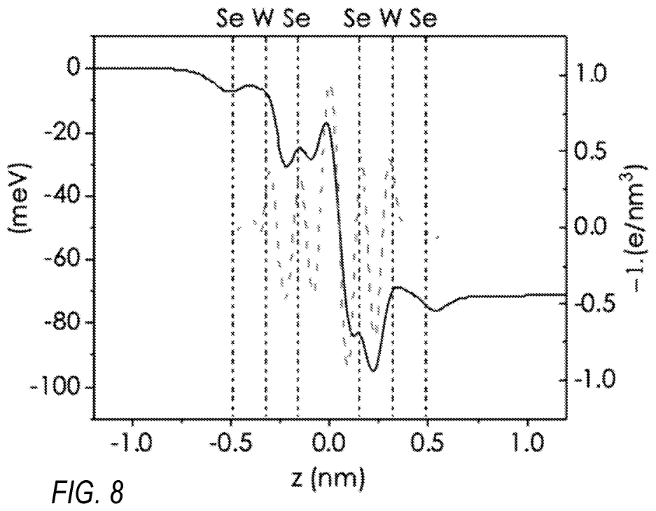

An AB stacked WSe₂ bilayer, constructed from two relaxed monolayers, was allowed to relax, yielding a lattice constant of 3.29 Å and an interlayer distance (defined as the normal distance between adjacent Se ions of the two layers) of 3.10 Å. Single-point electron density calculations were then performed on the relaxed structure with a plane wave energy cutoff of 600 eV and a k-point mesh of 12×12×1, setting a vertical vacuum size of 10 nm to avoid interactions between adjacent bilayer images. To evaluate the vertical polarization, a dipole moment correction was employed. The potential profile along the normal direction of bilayer WSe₂ is plotted in FIG. 8. The resulting difference between the electrostatic potential values obtained above the top and below the bottom surfaces is 69 meV, which defines the vertical polarization of the system.

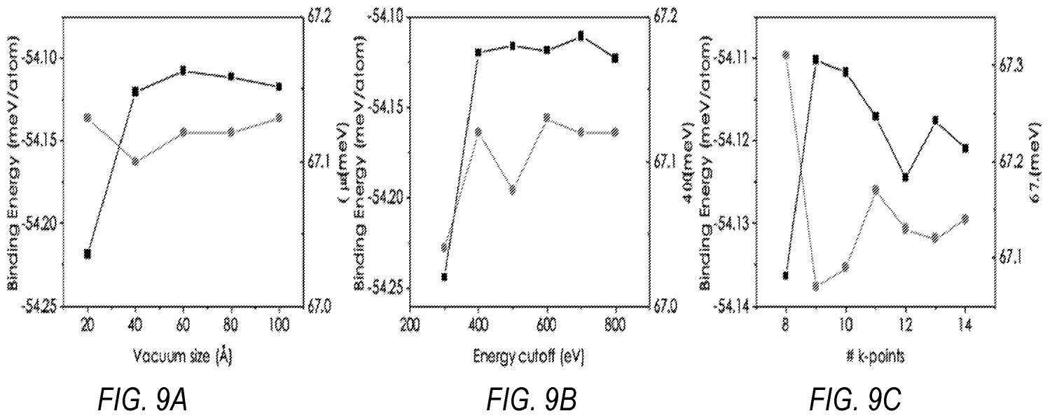

Convergence tests of the VASP calculations (see FIG. 9) with respect to the vacuum size, energy cut-off, and number of k-points indicate that our choice of parameters leads to binding energies that are converged to within 0.006, 0.002, and 0.007 meV/atom, respectively. Correspondingly, the electrostatic potential difference converges to within 0.01, 0.05, and 0.04 meV with respect to the vacuum size, energy cut-off, and number of reciprocal space k-points, respectively.

In FIG. 3E, further explored was the thickness dependence of the system's polarization. To this end, multilayer systems were constructed including the AB stacked bilayer, atop of which a few AB or AA′ stacked WSe₂ layers were added. Following optimization, single point potential profile calculations were performed as detailed above.

### Calculation of Doping-Induced Depolarization in WSe₂ and MoS₂

Doping calculations of bilayer WSe₂ and MoS₂ were performed using the fractional nuclear charge pseudoatom approach, allowing for simulating doping densities in the experimentally relevant range. To this end, we use pseudopotentials (PPs) generated for atoms with fractional nuclear charge. These calculations were performed using the open source package Quantum Espresso, instead of VASP that was used herein, allowing us to construct appropriate PPs. We first generated Rappe-Rabe-Kaxiras-Joannopoulos (RRKJ) PPs, including spin-orbit interactions, using the ld1.x program of the plane-wave pseudopotential Quantum Espresso package. The nuclear charge of the pseudoatom was set to the original charge of the neutral element plus a small fractional charge ε. For example, the nuclear charge of a doped pseudo W atom was set to Z=74±ε. The valence electronic charge was changed accordingly to maintain neutrality of the unit-cell, with an electron configuration given by [Xe]4f¹⁴6s²6p⁰5d^{4±ε}. A set of PPs were generated by setting ε=10⁻⁹, 10⁻⁸, . . . , 10⁻² for all W atoms in the bilayer system, corresponding to doping densities of Δn_{2D}=2.1×10⁷, 2.1×10⁸, . . . , 2.1×10¹³ cm⁻², respectively. A similar procedure was used to generate MoS₂ PPs with fractional nuclear charge and valence charge. For example, for a pseudo Mo nuclear charge of Z=42±ε, the electron configuration was set to [Kr]5s²5p⁰4d^{4±ε}.

Single point calculations were performed using the generated PPs to obtain the electron density and the corresponding electrostatic potential profiles. To this end, we employed the PBE generalized-gradient density functional approximation and the Grimme-D3 dispersion correction with BJ damping, as implemented in Quantum Espresso. A plane wave energy cutoff of 60 Ry (816.34 eV) was used with a k-mesh of 12×12×1, and a vertical vacuum size of 10 nm was set to avoid interactions between adjacent bilayer images. Fermi-Dirac smearing was used to enhance the convergence of the self-consistent cycle. To obtain the electrostatic potential profiles, a dipole moment correction was used.

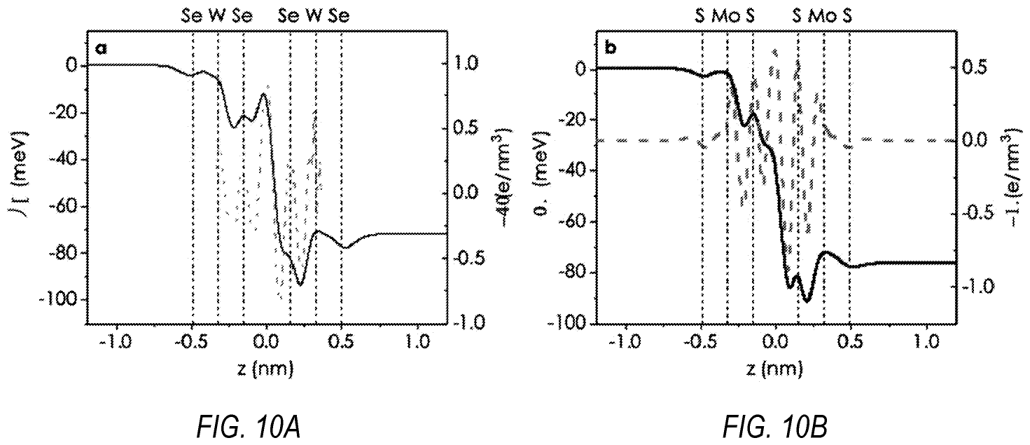

As in the procedure discussed herein, AB-stacked WSe₂ and MoS₂ bilayers were first constructed and optimized, yielding lattice constants of 3.29 Å and 3.16 Å and interlayer distances of 3.05 Å and 2.95 Å, respectively. The resulting electrostatic potential drops were 71 meV and 76 meV for the undoped WSe₂ and MoS₂ bilayers, respectively. Note that little difference (2 and 6 meV for WSe₂ and MoS₂, respectively) was found between the potential drops calculated by VASP in section S4 and those obtained using Quantum Espresso. The potential and charge density profiles along the vertical direction for the two bilayers are shown in FIG. 10.

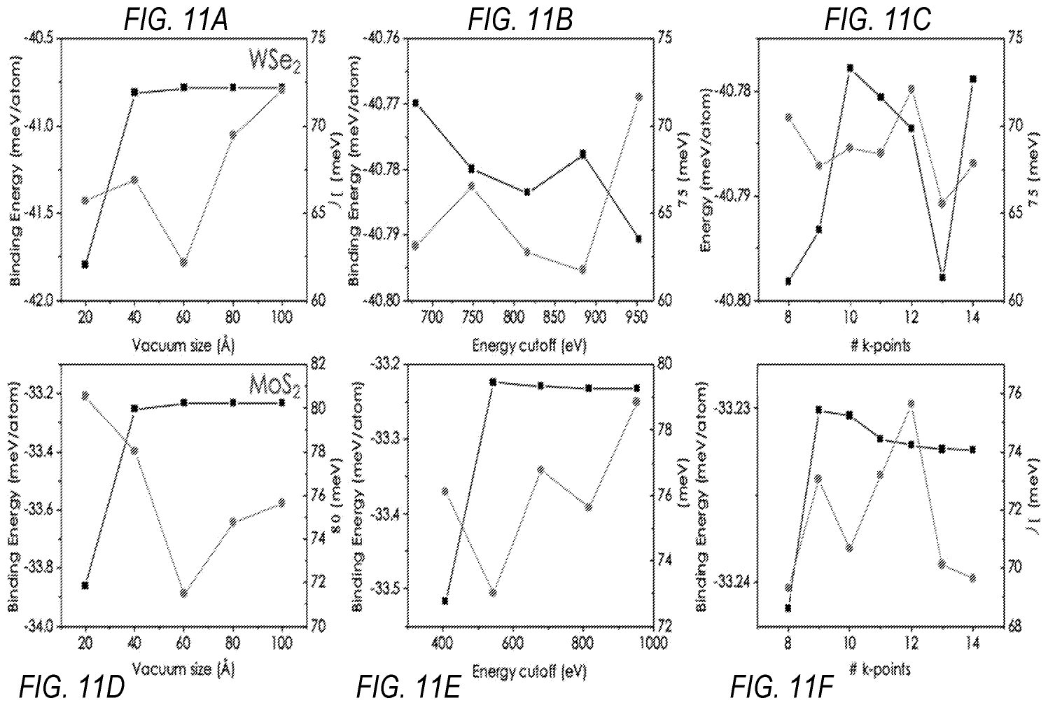

Convergence tests for the Quantum Espresso calculations (see FIG. 11) with respect to the vacuum size, energy cut-off, and number of k-points indicate that our choice of parameters leads to WSe₂ (MoS₂) binding energies that are converged to within 0.0003 (0.0003), 0.004 (0.003), and 0.003 (0.0004) meV/atom, respectively. Correspondingly, the electrostatic potential difference converges to within 2.6 (0.9), 3.8 (1.1), and 3.6 (2.4) meV with respect to the vacuum size, energy cut-off, and number of reciprocal space k-points, respectively.

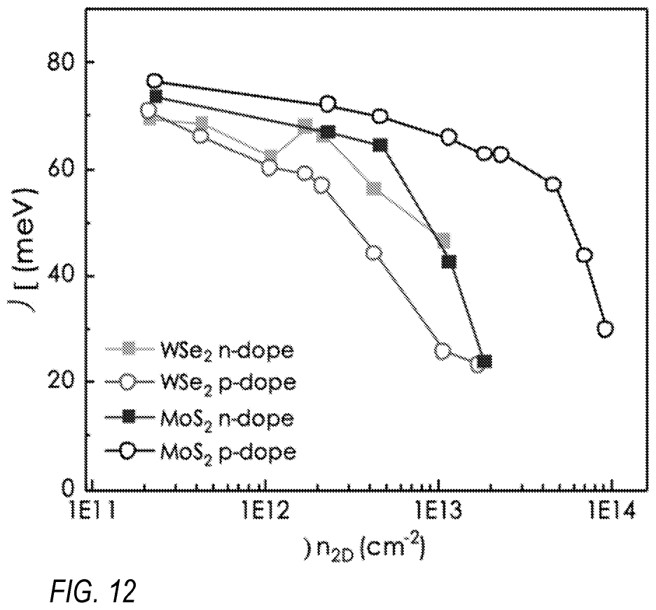

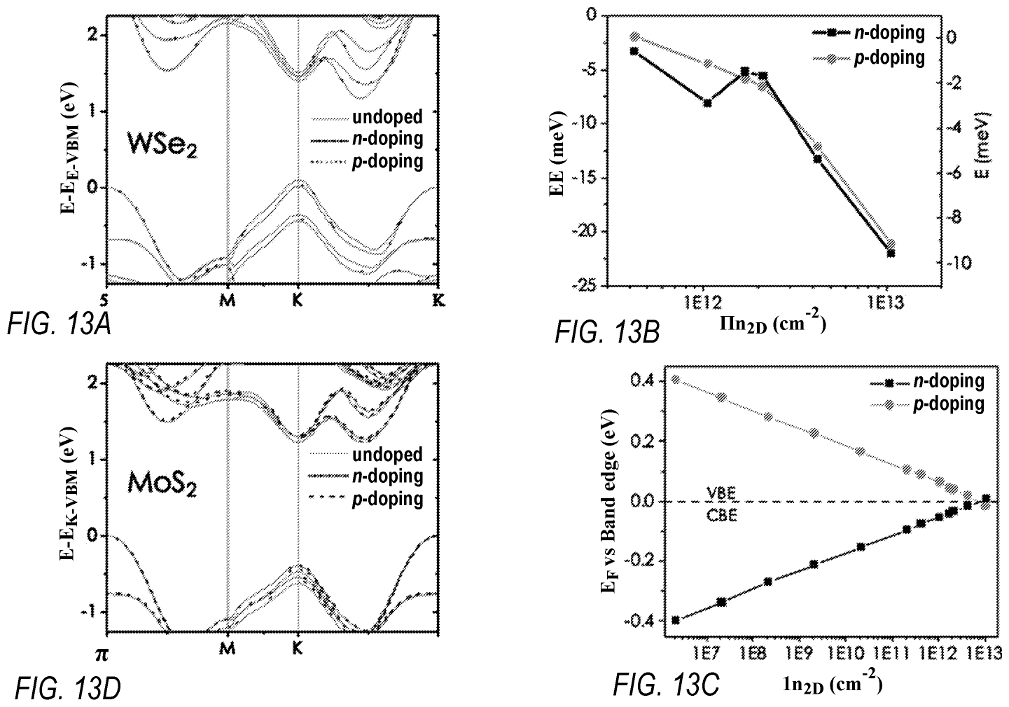

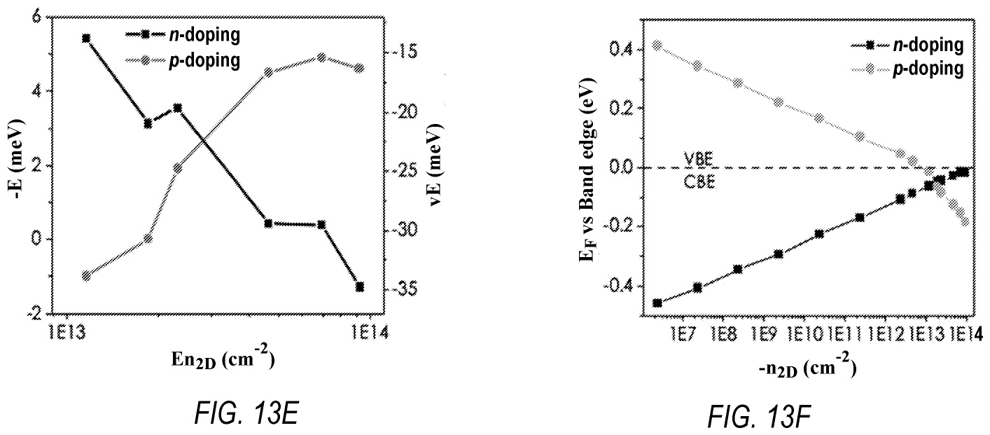

Doping of the WSe₂ and MoS₂ bilayers was performed by charging the metal nuclei. As discussed in the main text, up to a system dependent hole or electron charge density, the polarization remains mostly unaffected, following which a polarization drop is clearly seen (see FIG. 12). We note that the fractional nuclear charge pseudoatom doping approach adopted in this study remains valid as long as variations in the calculated band-structure, induced by the nuclear pseudo charging, are negligible. To confirm that our calculations satisfy this condition, we compare the bandstructures of the undoped and doped WSe₂ (FIG. 13A) and MoS₂ (FIG. 13D) bilayers up to the highest doping density considered. Our results clearly demonstrate merely minor deviations of the band-structures of the doped systems from those of the undoped counterparts. The energy difference between the topmost K and Γ valence band points for the doped and undoped systems is presented in FIGS. 13B and 13E for WSe₂ and MoS₂, respectively. Larger energy differences at higher doping levels result from the depolarization shown in FIG. 11. As an additional validity test, the doping-induced WSe₂ and MoS₂ Fermi level shifts are presented in FIGS. 13C and 13F, respectively, exhibiting the expected logarithmic dependence up to doping densities of 1×10¹³ cm⁻².

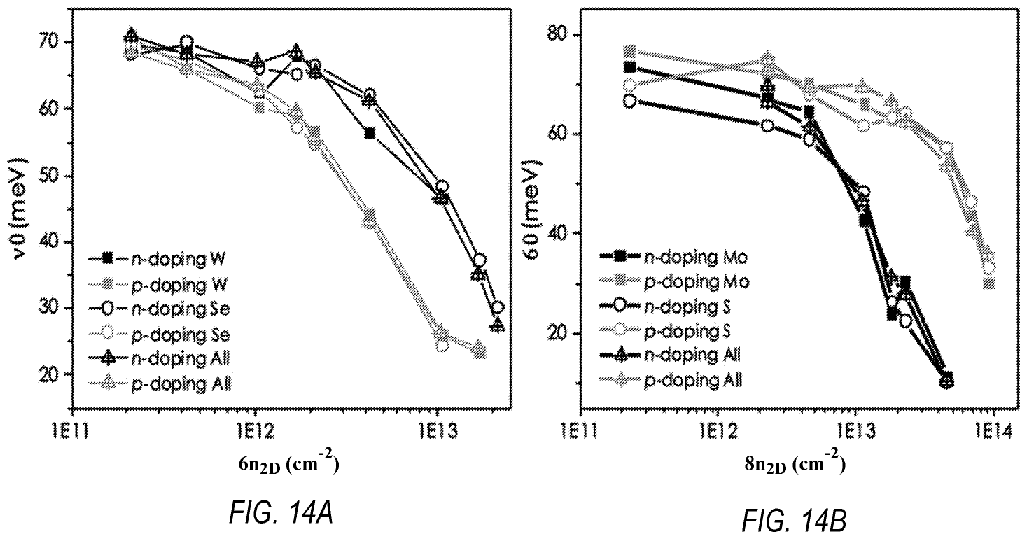

To demonstrate that our conclusions are independent on the choice of doping only via the metal atoms, we repeated the calculations by doping only via the chalcogen nuclei or doping all nuclei (see FIG. 14). Consistent results are obtained regardless of the doping scheme.

### Effect of Polarization on the Band-Structure

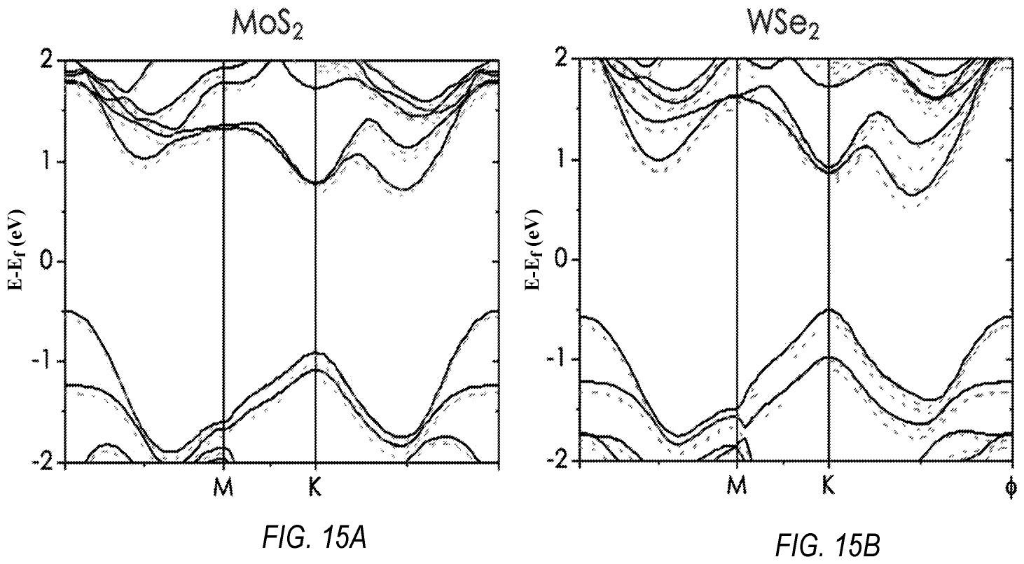

To evaluate the effect of the emerging polarization on the band structure, we compare in FIG. 15 the band structure of the anti-parallel AA′ stacked undoped bilayers with those of the parallel AB stacked counterparts, all evaluated at the same level of theory as described herein. The results clearly demonstrate band splitting of both the conduction and the valence bands at the K point. Notably, this splitting is of the order of the calculated vertical potential drops, indicating that the emerging polarization is indeed causing the splitting.

1.-31. (canceled)

32. A material in a form of a multilayer of two or more layers of a doped 2D material exhibiting in-plane conductivity, wherein each layer having a polarization pointing in a direction normal to the multilayer plane and opposite to the direction of polarization of any adjacent layer.

33. The material according to claim 32, wherein each of the material layers is formed of a 2D semiconductor material.

34. The material according to claim 33, wherein the 2D material is a diatomic hexagonal material.

35. The material according to claim 34, wherein the diatomic hexagonal material is selected from hexagonal-boron-nitride (h-BN), transition-metal-dichalcogenides (TMD), hexagonal-aluminum-nitride (h-AlN), hexagonal-zinc-oxide (h-ZnO), and hexagonal-gallium-nitride (h-GaN).

36. The material according to claim 34, wherein the 2D material is a transition-metal-dichalcogenides (TMD) selected from MoS₂, WS₂, MoSe₂ and WSe₂.

37. A conductive stacked multilayer diatomic hexagonal material or a conductive stacked multilayer structure formed by orienting any two stacked layers of a doped diatomic hexagonal material into a stacked (substantially) parallel lattice orientation to induce internal interfacial electric field normal to the layers plane at an interface between the two stacked material layers and in-plane conductivity, wherein the multilayer is n-doped or p-doped.

38. The material according to claim 32, wherein the doped multilayer is formed by chemical doping of the 2D materials prior to forming the multilayer structure.

39. The material according to claim 32, wherein the doped multilayer is formed by electrostatic doping of a preformed multilayer.

40. The material according to claim 32, comprising two or more stacked layers of a 2D material exhibiting out-of-plane switchable polarization and comprising free charge carriers of a density that is at least 10¹⁰ cm⁻² evenly distributed in the multilayer.

41. The material according to claim 40, comprising two or more layers of a TMD material stacked in a substantially parallel lattice orientation and exhibiting out-of-plane switchable polarization and comprising free electrons or holes of a density that is at least 10¹⁰ cm⁻² evenly distributed in the multilayer.

42. A device implementing a material according to claim 32.

43. A multi-switch polarization device having in-plane conductivity, the device comprising a plurality of out-of-plane switchable polarization states, the multilayer material comprising two or more stacked layers of a 2D material, wherein at least one of the layers formed of the 2D material is doped with charge carriers or holes (electrons or holes) that are (substantially) evenly distributed in the material layer(s).

44. The device according to claim 43, comprising a pair of electrodes, each of said electrodes being positioned at an edge of the layers of the multilayer material.

45. The device according to claim 43, comprising a top electrode and a bottom electrode.

46. The device according to claim 43, being selected from non-volatile memory devices, MEMS, photovoltaic cells, field effect transistors, memristors, and polar diodes.

47. The device according to claim 43, comprising two or three or more layers of one or more transition metal dichalcogenide (TMD), wherein the layers are artificially stacked in a parallel lattice orientation and encapsulated by thin flakes of a non-polar hexagonal boron nitride (h-BN), placed atop a graphite or gold metallic electrode.

48. The device according to claim 43, being a photovoltaic cell, an electro-mechanical generator, a dense information manipulation and storage device, a motion detection device, an opto-mechanical modulator, or an electronic device combining in-plane conductivity and internal out-of-plane polarization.

49. The device according to claim 43, being a photovoltaic device.

50. A photovoltaic device comprising a multi-switch polarization arrangement having in-plane conductivity, the arrangement being a multilayer stack of two or more layers of at least one 2D material, wherein at least one of the layers formed of the 2D material is doped with charge carriers (electrons or holes) that are (substantially) evenly distributed in the material layer(s), the device comprising a pair of electrodes positioned at the stacked layers edges and optionally a top electrode and a bottom electrode.

51. A process for constructing a multilayer structure according to claim 32, the process comprising:
orienting any two stacked layers of one or more 2D materials into a stacked (substantially) parallel lattice orientation, wherein one or more of the layers of the structure are formed of a doped 2D material; or
orienting any two stacked layers of one or more 2D materials into a stacked (substantially) parallel lattice orientation, to obtain the multilayer structure and exposing said structure to electrostatic doping to induce in-plane conductivity.
